(19) United States
(12) Patent Application Publication
(10) Pub. No.: US 2026/0309817 A1
(43) Pub. Date: Oct. 8, 2026

(54) SYSTEMS AND METHODS FOR PERIODIC MAGNETIC INTERFERENCE CANCELLATION IN ZERO-FIELD OPTICALLY PUMPED MAGNETOMETERS USING INTERNAL COMPENSATION COILS

(71) Applicant: QuSpin, Inc., Louiville, CO (US)

(72) Inventors: Vishal Shah, Louisville, CO (US); Cody Doyle, Broomfield, CO (US); James Osborne, Erie, CO (US)

(73) Assignee: QuSpin Inc., Louisville, CO (US)

(21) Appl. No.: 19/328,409

(22) Filed: Sep. 15, 2025

Related U.S. Application Data
(60) Provisional application No. 63/785,245, filed on Apr. 8, 2025.

(51) Int. Cl. G01R 33/26

(52) U.S. Cl. CPC G01R 33/26

(57) ABSTRACT

An optically pumped magnetometer (OPM), such as a zero-field OPM, uses internal compensation coils, or closely associated external compensation coils, with a periodic cancellation or compensation path that suppresses periodic magnetic interference at the sensor. A signal-processing unit isolates targeted components from the OPM output, applies programmable gain and phase selected modulo 2π to accommodate aggregate latency, and drives the compensation coils to synthesize counter-fields local to the sensing volume. In embodiments, a separate DC/low-frequency feedback loop using external coils coarsely nulls static and slow variations, and a summing-node embodiment combines both drives on the same axis. The device and technique support single-axis or triaxial operation, multi-tone cancellation with per-tone phase/gain, and adaptive algorithms that track drift and mitigate cross-axis coupling. The device and approach prevents saturation, restores linearity from non-linear start-up, and reduces shielding and reference-sensor requirements, enabling high-fidelity measurements in shielded, lightly shielded, and unshielded environments.

The following is an application under 35 U.S.C. 111(a). This application claims priority to U.S. Provisional application No. 63/785,245 filed Apr. 8, 2025.

This invention was made with government support under Grant No. SB1MH136846 awarded by the National Institutes of Health. The government has certain rights in the invention.

### FIELD

This disclosure relates to magnetic field sensing and, more specifically, to systems and methods for mitigating periodic magnetic interference, e.g., mains and harmonics, in optically pumped magnetometers, including zero-field OPMs.

### BACKGROUND

Often optically pumped magnetometers (OPMs), particularly zero-field (ZF) alkali vapor OPMs, ZF-OPMs, operating based on spin-exchange relaxation-free (SERF) [1], [2] or related systems, offer extremely high magnetic field sensitivity, often achieving levels around 10 fT/√Hz or better. This sensitivity makes them ideal for various demanding applications, including biomagnetism, such as magnetoencephalography (MEG), including OPM-MEG and magnetocardiography (MCG), as well as non-destructive testing, geological surveying, and fundamental physics research.

A fundamental characteristic of ZF-OPMs is their requirement for operation in a near-zero magnetic field environment, typically below a few tens of nanotesla (nT), to maintain optimal sensitivity and linearity. The operational linear dynamic range, where linearity might be within approximately 1%, can be quite narrow, potentially on the order of +/−1 nT, related to the sensor's magnetic resonance linewidth, often only a few nT. Outside this range, the OPM response becomes significantly non-linear in amplitude and phase, and the sensitivity degrades, making accurate measurements difficult. Ambient magnetic fields, especially in laboratory, clinical, or industrial settings, contain significant interference sources that far exceed these operational limits.

For these reasons, ambient magnetic fields, including static or quasi-static fields and low-frequency environmental drifts, must be removed. More problematically, time-varying fields, particularly periodic interference from alternating current (AC) power lines, e.g., 50 or 60 Hz, and their harmonics, as well as other sources such as railway power systems, ~16-25 Hz, HVAC equipment, and medical devices, can reach amplitudes of tens to hundreds of nT, and in some environments up to μT-level, and can drive the OPM far into its non-linear regime or saturate it entirely; these components must also be removed.

Traditionally, passive magnetic shielding using Magnetically Shielded Rooms (MSRs) has been the primary solution for removing both the residual DC and AC magnetic field noise in the OPM operational band, typically DC to a few hundred Hz. However, MSRs, particularly those with multiple layers, remain expensive and limit wide-scale adoption of technologies like OPM-MEG. Active magnetic field compensation using external coils and feedback systems [3], [4] is under investigation to replace or reduce the need for shielding but faces challenges.

One of the key challenges is that high-bandwidth feedback for broadband cancellation requires reference sensors possessing both extremely low noise and high bandwidth. This combination is difficult because few sensor options suitable for this task are readily available. Fluxgates or ZF-OPMs themselves can be used as reference sensors, but they face challenges when applied to broadband active cancellation [5]. The fluxgate noise floor is significantly higher than the OPM noise floor. Implementing a fast active cancellation system using fluxgates to remove both DC and AC fields invariably increases the environmental noise level within the measurement band to the noise floor of the fluxgates, which is several orders of magnitude greater than the desired noise floor in the fT/√Hz region. Using OPMs as reference sensors is another option due to their low noise, but they typically lack the bandwidth required to implement a fast feedback lock needed to drive active cancellation coils with sufficiently high bandwidth for broadband correction. For these reasons, both fluxgates and similar sensors, as well as ZF-OPMs, are often more suitable for correcting DC or slowly drifting background fields alone, and not for higher frequencies via high-speed feedback.

With active stabilization primarily addressing the DC/LF components, if the background field is held below approximately 10 nT, ZF-OPMs generally become operational. However, the next typical major practical challenge is strong periodic interference, such as powerline noise, which can still be several tens of nT or greater. When the amplitude of this residual AC interference exceeds the OPM's linear dynamic range, the sensor ceases to function correctly. This failure prevents the effective application of subsequent advanced signal processing techniques, such as beamforming, signal space separation (SSS), independent component analysis (ICA) which rely on high-fidelity, linear data from an array of functioning sensors [6].

Therefore, there is a need for an instrument and method to specifically mitigate strong, periodic interference sources within the OPM sensor itself, enabling its proper operation even in environments with significant residual AC magnetic fields after DC/LF stabilization, without relying on expensive MSRs or high-bandwidth feedback systems limited by reference sensor performance.

### SUMMARY

A zero-field optically pumped magnetometer (ZF-OPM) with internal compensation coils is operated with a periodic cancellation path that targets one or more periodic magnetic interference components, e.g., mains and harmonics. A signal processing unit (SPU) isolates a selected component, or components, applies programmable phase, selected modulo 2π to compensate aggregate latency, and gain per component, and drives the internal coils to synthesize a counter-field at the sensor, thereby reducing the amplitude of the periodic interference component(s) experienced by the OPM. In certain embodiments, a DC/low-frequency (LF) feedback system with external coils coarsely nulls DC and slow drifts, while the periodic cancellation path handles the periodic components. Implementations include single-axis or triaxial operation and optional multi-tone, multi-harmonic, synthesis. Phase/gain may be fixed, user-calibrated, or adaptively tuned. The approach enables the OPM to remain operational even when residual AC interference amplitudes would otherwise exceed the sensor's linear dynamic range.

In one aspect the disclosure comprises A system for mitigating periodic magnetic interference, the system comprising: an optically pumped magnetometer (OPM) sensor having at least one sensitive axis and at least one of an internal compensation coil or a closely affixed external compensation coil aligned with the at least one sensitive axis, wherein the at least one of an internal compensation coil or a closely affixed external compensation coil is configured to generate a magnetic field local to the sensor; a signal processing unit configured to receive at least one output signal from the OPM sensor, isolate at least one periodic interference component at a target frequency from the at least one output signal, and generate at least one periodic processed signal by applying a programmable phase and a programmable gain to the at least one isolated periodic interference component; a coil driver configured to drive the at least one of an internal compensation coil or a closely affixed external compensation coil based on the at least one periodic processed signal to generate at least one cancellation magnetic field; wherein the at least one cancellation magnetic field substantially counteracts the at least one isolated periodic interference component at the OPM sensor; and wherein the programmable phase is selected modulo 2π to account for an aggregate system latency, thereby enabling effective cancellation at the target frequency for at least one of a fixed and a bounded aggregate latency.

In another aspect, the system may further comprises a system wherein the signal processing unit is configured to use a periodicity of the at least one periodic interference component to select, for the at least one periodic processed signal at the target frequency, a phase modulo 2π that accommodates the aggregate system latency, thereby enabling cancellation at the target frequency without requiring a control loop having bandwidth sufficient to suppress the target frequency.

In another aspect, the system may further comprise a system wherein the at least one output signal of the OPM sensor is initially non-linear or saturated due to the at least one periodic interference component and activation of the at least one periodic processed signal reduces the at least one periodic interference component such that the at least one output signal of the OPM sensor is reduced to within a linear operating range.

In another aspect, the system may further comprise a system wherein the signal processing unit is configured to derive at least one periodic interference component from at least one of a mains-locked timebase and a reference magnetometer, and apply the programmable phase and the programmable gain to synthesize the at least one periodic processed signal.

In another aspect, the system may further comprise a system wherein the signal processing unit is configured to isolate at least two periodic interference components and to generate at least two corresponding periodic processed signals that are combined to drive at least two compensation coils, each of the at least two compensation coils being one of the at least one of an internal compensation coil or a closely affixed external compensation coil.

In another aspect, the system may comprise a system wherein the signal processing unit is configured to isolate at least three periodic interference components and to generate at least three corresponding periodic processed signals that are combined to drive at least three compensation coils, each of the at least three compensation coils being one of the at least one of an internal compensation coil or a closely affixed external compensation coil.

In another aspect, the system may comprise a system wherein the signal processing unit is configured to perform independent isolation and phase/gain selection for the respective at least three periodic interference components to produce at least three corresponding periodic processed signals.

In another aspect, the system may comprise a system wherein the signal processing unit is configured to adaptively update at least one of the programmable phase and the programmable gain over time to maintain effective cancellation at the target frequency.

In another aspect, the system may comprise a system wherein the signal processing unit is further configured to generate a low-frequency feedback drive based on at least one output signal from the OPM sensor, and wherein the coil driver comprises a summing node configured to combine the low-frequency feedback drive with the at least one periodic processed signal to drive the at least one of an internal compensation coil or a closely affixed external compensation coil.

In another aspect, the system may comprise a system wherein the low-frequency feedback drive reduces DC and low-frequency variations and the at least one periodic processed signal reduces periodic components not fully removed by the low-frequency feedback drive.

In another aspect, the system may comprise a system wherein the signal processing unit comprises at least one filter configured to isolate the at least one periodic interference component, a phase-shift module, and a gain module implemented in at least one of a digital signal processor (DSP), a field-programmable gate array (FPGA), and a microprocessor executing program instructions.

In another aspect, the system may comprise a system wherein the at least one periodic processed signal is synthesized digitally by the signal processing unit. In another aspect, the system may comprise a system wherein the programmable phase is pre-calibrated for one or more target frequencies and optionally refined during operation.

In another aspect, the disclosure comprises a method for mitigating periodic magnetic interference in an optically pumped magnetometer (OPM), the method comprising: operating an OPM sensor having at least one compensation coil aligned with at least one sensitive axis; receiving at least one output signal indicative of a magnetic field along the at least one sensitive axis; isolating at least one periodic interference component at a target frequency from the at least one output signal; generating at least one periodic processed signal by applying a programmable phase and a programmable gain to the at least one isolated periodic interference component; driving the at least one compensation coil with the at least one periodic processed signal to synthesize at least one cancellation magnetic field that substantially counteracts the isolated at least one periodic interference component at the sensor; and wherein the programmable phase is selected modulo 2π to account for an aggregate system latency and time delay, thereby enabling effective cancellation at the target frequency for at least one of a fixed and a bounded aggregate latency and time delay.

In an aspect, the method may further comprise a method wherein cancellation at the target frequency uses the periodicity of the at least one periodic interference such that at least one of a fixed and a bounded system latency, and the time delay, are accommodated by phase selection modulo 2π, without requiring a control loop, with bandwidth sufficient to suppress the target frequency.

In an aspect, the method may further comprise a method further comprising initializing from a state in which the at least one output signal is saturated or non-linear due to the at least one periodic interference and continuing operation until the at least one periodic interference is reduced to within a linear operating range of the at least one output signal.

In an aspect, the method may further comprise a method further comprising isolating at least two periodic interference components and generating at least two corresponding periodic processed signals that are combined to drive the at least one compensation coil.

In an aspect, the method may further comprise a method wherein the OPM sensor is triaxial and the method is performed per axis with independent phase and gain selection for each respective sensitive axis.

In an aspect, the method may further comprise a method further comprising adaptively updating at least one of the programmable phase and the programmable gain over time to maintain effective cancellation at the target frequency.

In an aspect, the method may further comprise a method wherein a low-frequency feedback drive is applied to an external actuator coil distinct from the at least one of an internal or a closely affixed external compensation coil, and the periodic processed signal is applied to the at least one of an internal or a closely affixed external compensation coil.

In another aspect, the disclosure my comprise a system comprising: a plurality of optically pumped magnetometer (OPM) sensors, wherein each of the plurality of OPM sensors comprises at least one sensitive axis and at least one of an internal and a closely affixed external compensation coil aligned with the at least one sensitive axis; wherein each of the at least one of an internal and a closely affixed external compensation coil is configured to generate a magnetic field local to one of each of the plurality of OPM sensors; a signal processing unit configured to isolate, for each of the plurality of OPM sensors, at least one periodic interference component at a target frequency from at least one output signal of each of the plurality of OPM sensors, and to generate a periodic processed signal for each of the at least one output signals by applying a programmable phase selected modulo 2π and a programmable gain; and a coil driver configured for each of the plurality of OPM sensors to drive the at least one of an internal or a closely affixed external compensation coil based on the periodic processed signal to synthesize a cancellation magnetic field that substantially counteracts the at least one periodic interference component at each of the plurality of OPM sensors.

### DESCRIPTION OF THE DRAWINGS

FIG. 1 is a schematic illustration of a periodic cancellation system integrated with an OPM sensor, according to an embodiment of the disclosure.

FIG. 2 is a schematic which illustrates the signal processing stages within the signal processing unit shown in FIG. 1, according to an embodiment of the disclosure.

FIG. 3 is a schematic which illustrates the application of the periodic cancellation system to a triaxial OPM sensor, according to an embodiment of the disclosure.

FIG. 4 is a schematic which illustrates the typical operational context where the internal AC periodic cancellation system operates concurrently with a separate external DC/Low-Frequency (LF) compensation system.

FIG. 5 is a graph illustrating the reduction in the targeted periodic interference signal amplitude, e.g., at frequency f0, as measured at the OPM output or reflected in a residual error signal, over time when the AC periodic cancellation is activated.

FIG. 6 is a schematic which illustrates a hybrid noise cancellation architecture combining both periodic cancellation and feedback control methods using a single OPM sensor's output, according to an embodiment of the disclosure.

FIG. 7 is a graph showing a time trace of the output signal from the Z-axis of a ZF-OPM sensor.

FIG. 8 presents the noise amplitude spectral density (PSD) calculated from the time-domain data of the Z-axis OPM sensor output shown in FIG. 7, comparing the spectrum with and without 60 Hz periodic cancellation activated.

FIG. 9 is a schematic illustrating a method of a periodic cancellation system for mitigating periodic magnetic interference in AC cancellation system 100, 200 that may be utilized independently for each OPM axis and each periodic frequency requiring removal.

FIG. 10 is a schematic illustrating a method for concurrent AC periodic cancellation and DC/LF feedback.

FIG. 11 is a schematic illustrating a method for stabilizing an OPM signal using a hybrid summing node configuration.

Before explaining the disclosed embodiments of the present disclosure in detail, it is to be understood that the disclosure is not limited in its application to the details of the particular arrangement shown, since the disclosure is capable of other embodiments. Also, the terminology used herein is for the purpose of description and not of limitation.

### DETAILED DESCRIPTION

### Definitions

As used herein, an “optically pumped magnetometer” or “OPM” is a highly sensitive magnetic field sensor is a magnetic-field sensor that detects magnetic fields using atom-light interactions.

As used herein, a “zero-field optically pumped magnetometer” or “ZF-OPM”, is an OPM configured for high sensitivity in a near-zero magnetic-field environment.

As used herein, a “signal processing unit” or “SPU” refers to one or more processors or logic devices, e.g., microcontroller, DSP, FPGA, ASIC, or equivalents, configured to receive OPM signals and perform operations such as filtering, phase adjustment, gain adjustment, and optional adaptive updating of parameters. The SPU may be integrated with the OPM or implemented as a separate unit.

As used herein, a “digital signal processor” or “DSP”, is a processor architecture optimized for digital signal processing and may serve as, or be part of, an SPU.

As used herein, a “field-programmable gate array” or “FPGA” is a configurable integrated circuit that can be programmed after manufacturing and may serve as, or be part of, an SPU.

As used herein, “filtering” refers to processing that selectively passes or suppresses signal components to facilitate estimation or extraction of components of interest.

As used herein, ‘magnetic-field-component’ means the projection of the magnetic-field vector, often denoted as B, along a given OPM sensitive axis, x, y, or z, which is the quantity measured and reported for that axis.

As used herein, “periodic cancellation” or “periodic cancellation path” refers to a path in which an estimate of one or more periodic interference components (e.g., power-line fundamentals and harmonics) is isolated and, for each targeted tone, phase-aligned and gain-scaled in the SPU to generate a periodic processed signal. The resulting drive is applied to a compensation coil to synthesize a counter-field at the sensor.

As used herein, ‘feedback system’ refers to a loop that processes an OPM output 125 to generate a feedback drive that reduces magnetic-field components at the sensor. The loop bandwidth and latency may be selected for a given deployment and need not be limited to a particular frequency range.

As used herein, a “periodic processed signal” means the output of the signal processing unit (SPU) obtained by isolating a periodic interference component at a target frequency (f₀) and applying programmable phase (φ) and gain (G), the result being a drive signal for a compensation coil.

As used herein, a “target frequency” or “f₀” means the frequency of a periodic interference component selected for cancellation, e.g., a 50/60 Hz power-line fundamental or a harmonic.

As used herein, “phase selected modulo 2π” means the phase is chosen within an equivalent 2π wrap so that, after accounting for latency in sensing, processing, and actuation, the synthesized field is in the desired counter-phase at the sensor.

As used herein, a “tone” means a periodic component at a single frequency. As used herein, “per-tone” means that phase and gain are selected and applied independently for each targeted frequency component.

As used herein, a “summing node” means an analog and/or digital summation stage that combines multiple drive signals, e.g., a low-frequency feedback drive and one or more periodic processed signals, to produce a composite coil drive.

As used herein, a “low-frequency (LF) feedback drive” means the output of a feedback controller configured to reduce DC and slowly varying magnetic field components in the measurement volume using compensation coils.

As used herein, “phase adjustment (φ)” refers to adjusting the phase of a periodic signal.

As used herein, “signal gain” or “gain” or “G” refers to scaling the amplitude of a signal.

As used herein, a “coil driver” is circuitry that converts a control or drive signal into current for a compensation coil to generate a magnetic field.

As used herein, “internal compensation” refers to generating a corrective magnetic field local to the OPM sensor head, for instance using coils integrated with, attached to, or closely affixed to the sensor head for the purpose of counteracting unwanted fields at the sensing volume.

As used herein, “internal compensation coil” or “compensation coil” are substantially orthogonal electromagnetic coils, recognizing practical misalignment on the order of a few degrees, that generate controlled magnetic fields to counteract unwanted fields at the sensor. In triaxial embodiments, coils are arranged to address substantially orthogonal axes. An internal compensation coil includes coils integrated with, attached to, or closely affixed to the sensor head.

A “closely affixed external compensation coil” is a coil or coils in close proximity to the sensor head.

As used herein, “electromagnetic coils” are conductors wound into a coil that produce a magnetic field when driven by current.

As used herein, a “sensor head” is the portion of the magnetometer that includes the sensing volume and, in some embodiments, integrated compensation coils.

As used herein, a “magnetic field” is a physical field associated with magnetic-flux-density vector (B).

As used herein, a “DC/low-frequency (LF) feedback system” is a control loop that reduces DC and slowly varying magnetic-field components in the measurement volume using compensation coils, optionally with reference-sensor input. The crossover band is an implementation choice and may vary by deployment, e.g., ~0.2-10 Hz.

As used herein, a “feedback controller” is logic, e.g., processor, DSP, FPGA configured to generate a feedback drive to stabilize the measurement environment, e.g., magnetic-field components, within a selected bandwidth.

As used herein, a “reference sensor” or “reference magnetometer” is an additional magnetometer used to sense ambient fields for control, estimation, or stabilization.

As used herein, a “fluxgate magnetometer” or “fluxgate sensor” is a magnetometer type commonly used as a reference sensor in active compensation systems.

As used herein, a “sensitive axis” is the direction in which the sensor is most responsive to magnetic fields. This axis is typically defined by the direction of the bias magnetic field or the modulation field used in the sensor's operation.

As used herein, “tesla” or “T” is a unit of magnetic flux density. One “nT” or nanotesla is equal to 10\hat{ }-9 tesla.

As used herein, “hertz” or “Hz” is the unit of frequency, representing the number of times a repeating event occurs per second.

As used herein, an “AC periodic cancellation path” (also, “AC cancellation path”) refers to a path that targets one or more periodic components. A “DC/low-frequency (LF) feedback path,” when present, reduces DC and slowly varying components. The two paths are coordinated to address complementary frequency regions with minimal interaction; specific band edges are implementation-dependent (e.g., a crossover on the order of ~0.2-10 Hz in some deployments).

As used herein, “fT/√Hz” or “femtotesla” per root hertz, is a unit of magnetic field sensitivity.

As used herein, a “field” is a magnetic field.

As used herein, the term “about” or “about the same” is construed encompassing variations consistent with measurement precision and ordinary engineering tolerances.

As used herein, the term “essentially” or “essentially the same” or “substantially” or “approximately” is construed as encompassing variations consistent with ordinary engineering practice and context.

As used herein, “several” is construed to be more than one to as many as five items.

Units referenced herein include Tesla (T), nanotesla (nT), hertz (Hz), and pT/√Hz, unless otherwise noted.

As used herein, “aggregate latency” means the total closed-loop delay from the arrival of a targeted periodic magnetic-field component within the OPM's measurement/sensing volume to the arrival of the corresponding counter-field produced by the compensation coil at that same volume. This delay includes latency from the OPM's own sensing/response, any demodulation/detection, digital filtering, computation, digital-to-analog conversion (DAC), and coil-driver electronics. For each targeted tone, the SPU chooses the drive phase (modulo 2π) so that, after accounting for this delay, the coil field is approximately 180° out of phase at the sensor.

“Fixed latency” means the delay is substantially constant for a deployment; “bounded latency” means the delay varies within a known range that the phase selection accommodates.

As used herein, “multi-tone” or “multi-harmonic” cancellation means operation in which two or more tones are targeted concurrently; the SPU computes and sums multiple periodic processed signals, each with independent phase and gain.

### DETAILED DESCRIPTION

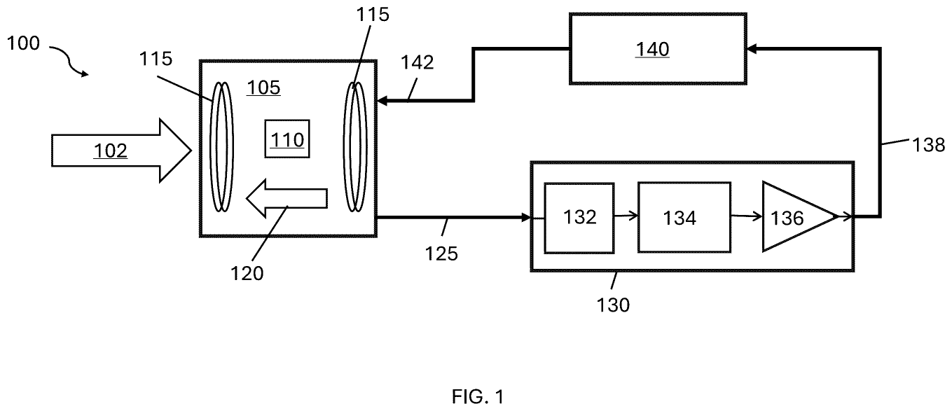

FIG. 1 is a schematic illustration of a periodic cancellation system 100 integrated with an OPM, according to an embodiment of the disclosure, which is a system for mitigating periodic magnetic interference. The periodic cancellation system 100 integrated with an OPM comprises a ZF-OPM or OPM sensor 105 designed to operate with high sensitivity in a near-zero magnetic field environment. The OPM 105 comprises at least one sensor 110, which may be a vapor cell with dimensions of at least a one, two, or a few millimeters, for measuring a magnetic field 102. The OPM 105 further comprises one or more compensation coils 115. The compensation coils 115 produce a cancellation field 120, being a magnetic field local to the sensor's 110 sensitive axis, which may be one axis such as x, or two axes, x and y, or three axes x, y, and z, or sensing volume. The compensation coils 115 are preferably internal to the OPM 105, but may alternatively be closely positioned external to the sensor package to generate the required counter-field. Because the compensation coils are typically cm-scale, e.g., ~0.5-2 cm characteristic dimension, and use few turns, e.g., 1, 2, or 3, their low inductance and capacitance provide kHz-class bandwidth with minimal attenuation or phase distortion. This ensures the compensation coils 115 can accurately generate the required cancellation fields at common interference frequencies, e.g., 50/60 Hz and their harmonics. The compensation coil 115 may be designed to generate local counter-fields up to the hundreds of nT range.

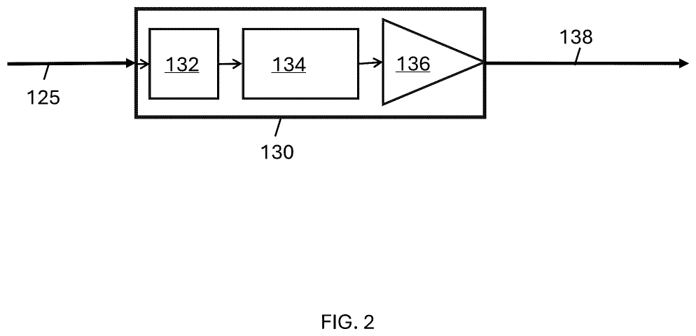

As shown in FIG. 1, the OPM 105 may comprise at least one sensor 110, being uniaxial, or two sensitive axes, being biaxial, or three sensitive axes, being triaxial. Each sensor 110 produces at least one output signal 125 related to the magnetic field component along that axis derived from the magnetic field 102. As illustrated in FIG. 1 the periodic cancellation system integrated with an OPM 100 further comprises a signal processing unit or SPU 130. The SPU 130 may be housed within the OPM 105, integrated as part of the OPM electronics controller and its signal processing capabilities, or may be a physically distinct unit. The SPU 130 receives one or more output signals 125 related to the magnetic field component along that axis derived from the magnetic field 102. The SPU 130 may comprise in one example a digital signal processor (DSP) that implements digital technology. In other examples the SPU 130 may comprise a field-programmable gate array (FPGA), or a suitably programmed microprocessor. As shown in FIG. 1 and detailed in FIG. 2, the SPU 130 is configured to perform filtering 132, for example employing a bandpass filter, f0, to isolate the target periodic interference frequency. The SPU 130 may apply a calculated phase shift 134, Phase Shift, φ or Φ0, and adjust the signal gain 136, being gain, G. The SPU 130 may use one or more of a filter or a phase shift, and/or adjust signal gain. Further, the SPU 130 may incorporate algorithms for adaptive tuning of the phase and gain parameters. The SPU 130 produces a processed signal 138. In the periodic cancellation path, the SPU 130 isolates the targeted periodic component(s), applies programmable phase (φ) (selected modulo 2π to account for latency) and gain (G), and outputs a processed signal 138 to the coil driver 140 to synthesize a counter-field at the sensor as in FIGS. 1-2.

In some embodiments, the SPU selects, for each targeted periodic component, a phase φ modulo 2π to compensate aggregate latency from sensing, digital processing, coil driver, and coil dynamics (phase selection and latency compensation). Practical implementations include: (i) a coarse-to-fine phase sweep that minimizes the residual at f₀; (ii) table-lookup of φ based on a measured or modeled latency; and/or (iii) adaptive tracking that continuously update φ to follow slow drift. For deployments with substantially fixed latency, φ is determined once, (=e.g., during installation, from the measured/modelled latency and then held. For deployments with bounded latency, or latency varying within a known range, φ is selected modulo 2π to achieve robust cancellation across the range, e.g., mid-range or min-max selection, and may be refined by adaptive tracking. This selection yields an effective ~180° counter-phase at the sensor even when absolute latency varies across deployments.

While in many embodiments the periodic component(s) are estimated from the OPM output after band-pass filtering, alternative embodiments derive the estimate from any one or more of a known timebase, e.g., mains-locked timebase, mains-locked reference, a reference magnetometer, and/or a combined estimator that fuses OPM and reference inputs or periodic estimate sources. Any such estimate may be phase-adjusted, modulo 2π, and gain-scaled before drive synthesis.

As illustrated in FIG. 1, the processed signal 138 is received by a coil driver 140. The coil driver is an electronic circuit that receives the processed signal 138 from the SPU 130 and provides the necessary voltage or current, as a coil-drive signal 142, to drive the compensation coil(s) 115. In some embodiments intended for high-sensitivity operation, the coil driver 140 contributes <~10 fT/√Hz equivalent magnetic noise while delivering coil currents corresponding to cancellation fields up to the hundreds of nT. However, the periodic cancellation concept does not fundamentally rely on achieving this ultra-low noise level in the coil driver 140.

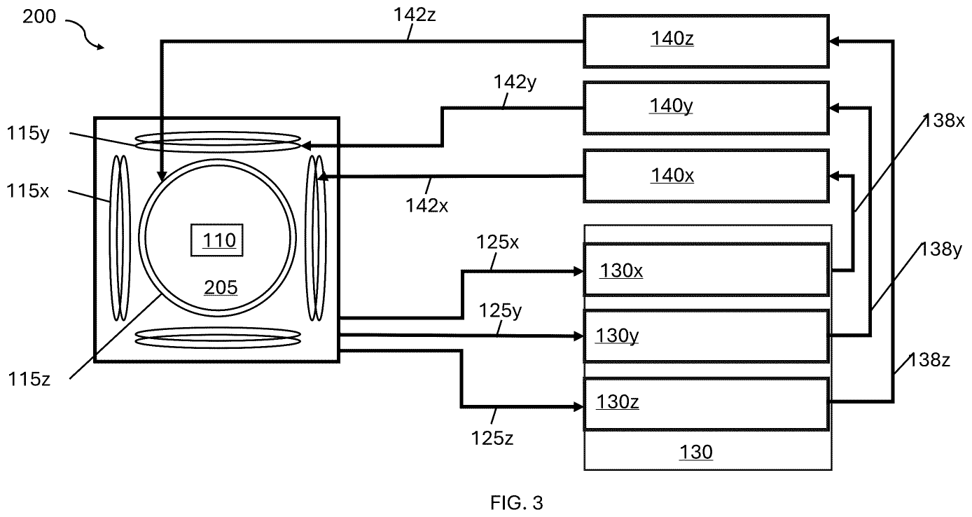

FIG. 3 is a schematic which illustrates the application of the periodic cancellation system 200 to a triaxial OPM 205, according to an embodiment of the disclosure, being another example of a system for mitigating periodic magnetic interference. A triaxial OPM 205 comprises three sets of compensation coils 115x, 115y, and 115z which produce a magnetic field component in the applicable axis, the x axis, y axis, and z axis, respectively. Although the compensation coils 115x, 115y, and 115z are illustrated as internal compensation coils, the compensation coils 115x, 115y, and 115z may be physically positioned externally to the triaxial OPM sensor 205. The triaxial OPM 205 may comprise one sensor 110 that senses from each of the respective axes, x, y, and z and produces signal outputs 125x, 125y, and 125z related to the magnetic field component along that axis derived from the magnetic field and potential periodic magnetic interference (not shown). In other examples the triaxial OPM may comprise two sensors 110, or three sensors that sense from different axes. An SPU 130 uses three different processing paths 130x, 130y, 130z one for each output signal 125x, 125y, and 125z to produce a processed signal 138x, 138y, and 138z for each respectively to feed the coil drivers 140x, 140y, and 140z. The coil drivers 140x, 140y, and 140z produce individual coil driver signals 142x, 142y, and 142z to control the compensation coils 115x, 115y, and 115z, respectively.

With reference to FIG. 3, even for ZF-OPMs primarily sensitive along only one or two axes, their operation can still be strongly impacted by high-amplitude magnetic fields on any axis that drives the sensor outside its dynamic range. For this reason, a particularly advantageous application of this disclosure involves OPMs equipped with triaxial measurement signal outputs 125x, 125y, and 125z corresponding to three orthogonal axes, and triaxial internal compensation coils 115x, 115y, and 115z. This allows interference fields to be actively cancelled along all three orthogonal axes independently, ensuring robust operation even when the interference direction is unknown or varying. While beneficial even for single or dual-axis cancellation, the disclosed periodic cancellation approach is most beneficial in triaxial ZF-OPMs as it enables suppression of periodic interference along all three axes.

In reference to axis coupling and decoupling, for instance in triaxial embodiments, modest cross-axis coil-to-field coupling may be present. Per-axis parameters {φₓ, Gₓ}, {φ_{y}, G_{y}}, {φ_{z}, G_{z}} are tuned independently. In embodiments where a cross-coupling matrix is characterized, the SPU optionally applies a 3×3 decoupling transform, or iterative compensation, so that each synthesized drive predominantly affects its intended axis at the sensing volume.

With reference to FIG. 3, a system for mitigating periodic magnetic interference 100, 200 can be configured to cancel multiple distinct periodic interference frequencies simultaneously, for example, by using parallel processing paths within the SPU 130x, 130y, 130z one for each output signal 125x, 125y, and 125z to produce a processed signal 138x, 138y, and 138z for each respectively to feed the coil drivers 140x, 140y, and 140z, but processing different frequencies from the same axis output, each targeting a different frequency, e.g., 60 Hz and 180 Hz, or by using more complex filtering and signal-synthesis techniques to generate a composite cancellation signal. While analog implementations are conceivable for output signal processing, digital implementation using DSPs or FPGAs may be advantageous due to the flexibility it offers in implementing precise filters, arbitrary phase shifts, gain control, and sophisticated adaptive algorithms as is illustrated in FIG. 2. To prevent clipping when multiple tones are summed, the SPU constrains per-tone gains to maintain coil-current headroom while achieving the targeted residual per component.

With reference to FIGS. 1-3 and description thereof, the determination of the phase shift (φ) and gain (G) can be achieved through various means. These include but are not limited to: using fixed values determined during factory calibration for standard interference frequencies, e.g., 50/60 Hz; performing a user-initiated calibration routine where the system actively adjusts φ and G to minimize the measured power at f0; or employing continuous adaptive algorithms, e.g., based on least mean squares (LMS) principles or other signal tracking methods, that automatically adjust φ and G during operation to compensate for drifts or changes in the interference characteristics. The choice of method depends on the specific application requirements and the nature of the interference.

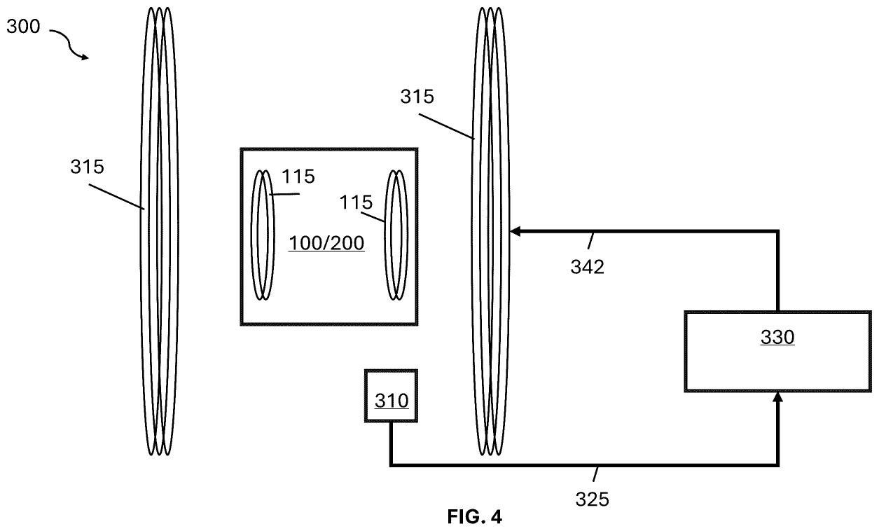

As shown in FIG. 4, the AC periodic cancellation system 100, 200 may operate concurrently with a separate DC/LF feedback stabilization system 300. The DC/LF feedback provides coarse nulling to bring the background field within a range where the OPM can operate; the AC periodic cancellation path then cancels the high-amplitude periodic components. Relative bandwidths, gains, and phases are selected for the deployment to achieve stable concurrent operation; no predetermined crossover is required.

With reference to FIG. 4, the DC/LF feedback system 300 comprises external DC/LF compensation coils 315 and, in some embodiments, a DC/LF reference sensor 310 that senses the field affected by the DC/LF compensation coils 315 and provides an output 325 to a DC/LF feedback controller 330. The DC/LF feedback controller 330 provides a drive, feedback signal 342, to the DC/LF compensation coils 315 to coarsely null DC fields and slow drifts in the measurement volume.

The AC periodic cancellation system is most effective for stable, predictable periodic interference such as power line fundamentals and harmonics. Performance when the periodic component drifts in frequency, contains harmonic distortion, or is only quasi-periodic depends on the selected filter design, FIG. 2, and the robustness of the adaptive algorithm in the SPU 130. Digital implementations offer flexibility to incorporate more advanced tracking if necessary.

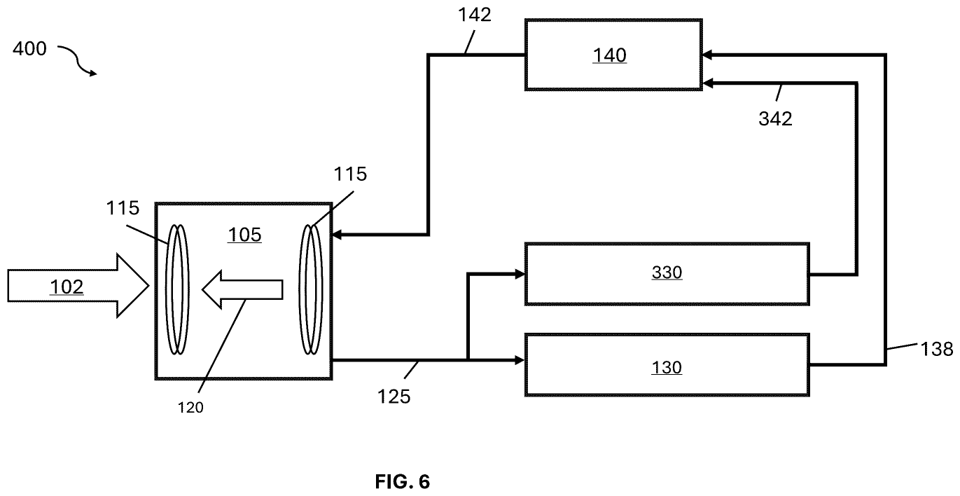

As depicted in FIG. 6, an AC periodic cancellation path 100, 200 targeting periodic signals is integrated into a hybrid framework 400. The OPM output 125 is processed by the SPU 130 to generate a processed periodic drive 138 for the internal compensation coils 115 via coil driver 140. In the primary embodiment, coil driver 140 implements a summing node that combines a low-bandwidth feedback signal with the periodic cancellation input 138 on the same axis. In alternative embodiments, a separate DC/LF power driver drives external DC/LF coils 315. The selection of bandwidths and crossover is deployment-dependent.

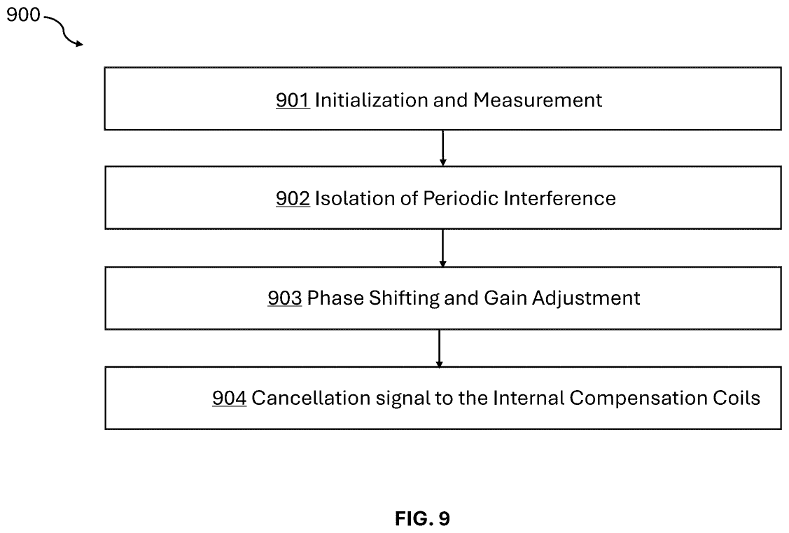

A periodic cancellation system for mitigating periodic magnetic interference, in one example an AC cancellation system 100, 200, which may be utilized independently for each OPM axis and each periodic frequency requiring removal, as shown for multiple axes in FIG. 3, proceeds as follows as a method 900 as illustrated in FIG. 9. In the initial phase 901, initialization and measurement, the OPM sensor FIG. 1, 105 begins measuring the total ambient magnetic field along its sensitive axis, or axes. If strong periodic interference is present, e.g., >1 nT amplitude, the sensor's 105 output signal 125 may initially be non-linear or saturated. Nonetheless, this output signal 125 contains information about the dominant periodic interference. In a second step 902, isolation of periodic interference, the output signal 125 from the OPM 105 is acquired by the SPU 130. A filter 132, for example a bandpass filter implemented digitally or with analog circuitry, is applied to isolate the signal component at or near the known frequency (f0) of the target periodic interference. In a third step 903, phase shifting and gain adjustment, the filtered signal, representing an estimate of the interference component, is phase-shifted 134, typically digitally, by an angle (φ) and its amplitude adjusted by a gain factor (G) 136. These parameters, φ and G, are determined either through prior calibration, presets, or via an adaptive algorithm. The goal is to compute a drive signal such that the resulting coil field is approximately 180 degrees out of phase with the interference field at the sensor and substantially matches its amplitude. Various control strategies may be employed within the SPU 130 to determine φ and G, potentially using techniques that adapt based on minimizing the residual signal power at f0. Robust algorithms are preferable to ensure stable convergence, especially during initialization from non-linear states. In a fourth step 904, cancellation signal application to the internal compensation coils, the calculated phase-shifted and gain-adjusted signal 138 is output by the SPU 130 to the coil driver 140, which in turn drives the corresponding internal compensation coil(s) 115. The driven internal or external compensation coil 115 generates a localized magnetic field FIG. 1, 120 that counteracts the ambient periodic interference field component. The OPM 105 measures the resulting, reduced, net field along that axis. This updated measurement inherently influences the signal processed in the next cycle.

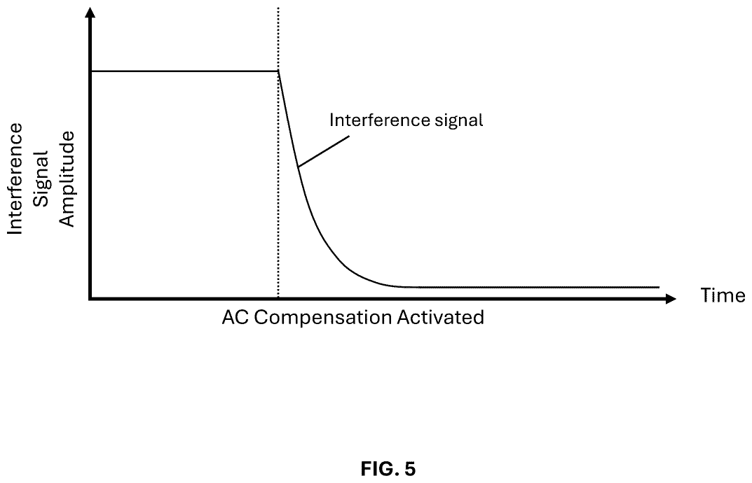

The system 100, 200 operates iteratively cycling through steps 901-904 illustrated in FIG. 9. Even with fixed parameters (φ, G), the reduction in interference changes the OPM output 125, leading to a refined cancellation signal in the next cycle. If adaptive algorithms are used, parameters (φ, G) are also updated based on the residual interference. Startup from non-linear states. If the OPM output is initially non-linear or saturated by periodic interference, the SPU may: (i) apply a narrow band-pass at f₀ to obtain a conditioned estimate; (ii) conduct a phase sweep to find a coarse minimum of the residual; and (iii) ramp gain G from a low value to avoid overshoot. This staged procedure reduces the targeted periodic component to within the linear range and then hands off to steady tracking. The system 100, 200 is designed to converge over a characteristic time period as is illustrated in FIG. 5 towards a state where the amplitude of the targeted periodic interference component, or interference signal, is reduced to a level within the OPM's approximate linear operating range, e.g., typically targeting below 1 nT amplitude. FIG. 5 is a graph illustrating the reduction in the targeted periodic interference signal amplitude, e.g., at frequency f0, as measured at the OPM output or reflected in a residual error signal, over time when the periodic cancellation system 100, 200, 300 is activated. Through use of the disclosed system and method the interference signal is reduced or converged and the OPM can operate linearly, providing high-fidelity measurements of the desired signals superimposed on the now significantly attenuated interference.

As shown in FIG. 3 and described above, triaxial OPMs with three independent internal coils 115x, 115y, 115z enable independent cancellation along all axes and are particularly advantageous when the interference direction is unknown or varying. Multi-frequency cancellation, e.g., fundamental and harmonics, is implemented as in FIG. 2 and Example 2 using parallel paths or composite synthesis in the SPU 130. Determination of φ and G may follow factory presets, user calibration, or adaptive tracking, as described above.

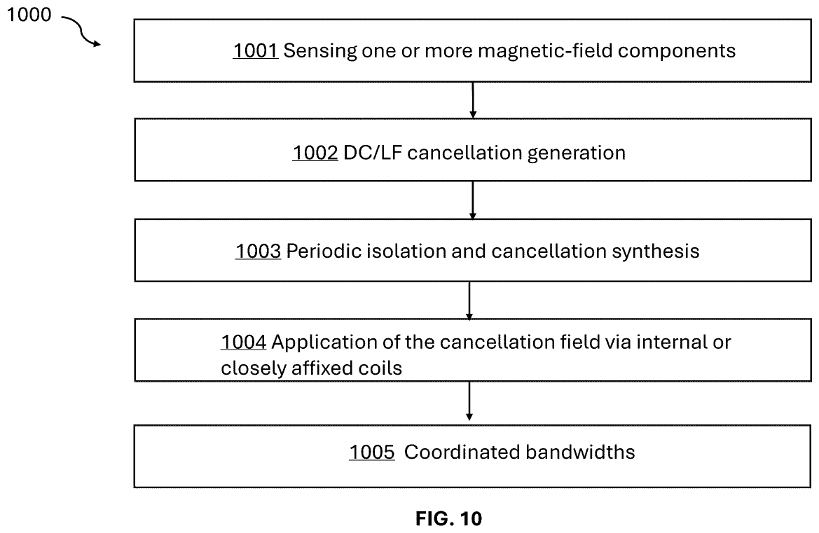

As shown in FIG. 10, method 1000 operates the system of FIG. 3 with concurrent DC/LF feedback and periodic cancellation. In step 1001, the OPM 105 senses one or more magnetic-field components and produces outputs 125x, 125y, 125z. In step 1002, a DC/LF feedback controller 330 generates a low-frequency feedback drive 342, optionally using a reference sensor 310, to reduce DC and slowly varying components via external compensation coils 315. In step 1003, the SPU 130 performs periodic isolation and synthesis to produce, for each targeted frequency, a periodic processed signals 138x, 138y, and 138z with programmable gain and phase selected modulo 2π. In step 1004, coil drivers 140x, 140y, 140z apply the periodic processed signals to the internal compensation coils 115x, 115y, 115z to generate cancellation fields local to the sensor. In step 1005, bandwidths and gains are coordinated for stable concurrent operation; no predetermined crossover is required.

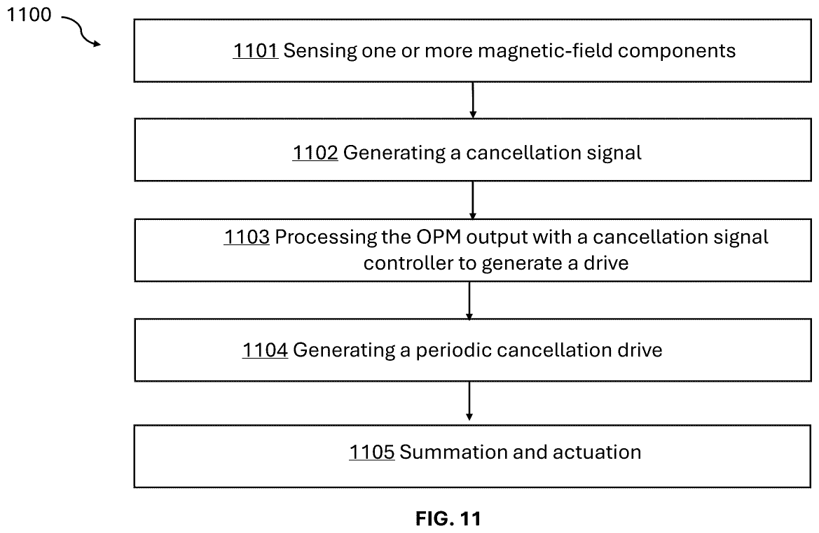

As illustrated in FIG. 11, method 1100 implements a same-axis summing-node embodiment. In step 1101, the OPM 105 senses one or more magnetic-field components to produce output(s) 125. In step 1102, the feedback controller 330 generates a low-frequency (LF) feedback drive, or cancellation signal to reduce DC and slowly varying components. In step 1103, the SPU 130 isolates one or more periodic components at target frequency(ies) and synthesizes, for each targeted tone, a periodic processed signal 138 with programmable gain and phase selected modulo 2π. In step 1104, a summing node within the coil driver 140 combines the LF feedback drive with the periodic processed signal(s) to produce a composite drive that is applied to the internal compensation coil(s) 115 on the same axis. In step 1105, summation and actuation is performed, with bandwidths and gains are coordinated for stable concurrent operation. No predetermined crossover is required.

With reference to FIGS. 1-4 and description thereof, the system 100, 200, 300 disclosed is most effective for stable, predictable periodic interference like powerline noise. Performance with signals that drift in frequency, have significant harmonic distortion, or are not perfectly periodic depends on the specifics of the bandpass filter design, as illustrated in FIG. 2, and the robustness and tracking capabilities of the employed adaptive algorithm. Digital implementations offer the flexibility to potentially incorporate more advanced algorithms to handle such cases if necessary.

As depicted in FIG. 6, an AC periodic noise-cancellation path 100, 200 that targets high-amplitude periodic signals can be integrated into a broader hybrid framework 400. In this framework, the OPM output 125, (and/or a reference sensor, may also be processed by a feedback controller 330 to reduce broadband or DC/LF components that are not addressed by the periodic cancellation path. This hybrid approach leverages techniques optimized for different interference types to improve overall performance.

Generating a feedback drive for external coils includes processing the OPM output 125, or an output from a reference sensor 310, with a feedback controller 330 to generate a drive 342 for external coils 315 that reduces magnetic-field variations over a bandwidth suitable for the deployment. The feedback loop may be configured to suppress DC, low-frequency, and any other components within its stable operating range.

Generating a periodic drive for internal coils comprises in parallel, processing the OPM output 125 through a periodic cancellation chain in SPU 130, including filter 132, phase 134, and gain 136, to isolate and target periodic interference components, e.g., mains and harmonics, that remain after operation of the feedback loop. Actuating separate coils comprises applying the periodic cancellation drive 138 to the internal compensation coil 115 via coil driver 140 to generate a cancellation field 120 that reduces the targeted periodic components at the sensor.

The feedback and periodic cancellation loops operate simultaneously, each acting on its own coil system. The feedback loop addresses slower and broadband variations within its capability, while the AC periodic cancellation path suppresses targeted periodic interference not fully removed by feedback. The control path bandwidths, gains, and phase characteristics are chosen to achieve stable operation without requiring a predetermined crossover frequency.

With reference to FIG. 4 and description thereof, the method for concurrent feedback and AC periodic cancellation using separate actuators is represented in the schematic of FIG. 10, a flow diagram of method 1000 for concurrent AC periodic cancellation and DC/LF feedback. The method 1000 comprises: sensing one or more magnetic-field components along an OPM sensitive axis 1001 using an OPM 105 disposed within internal compensation coils 115 to produce an OPM output 125; DC/LF feedback generation 1002; periodic isolation and cancellation synthesis 1003; application of the cancellation field via internal coils 1004; and coordinated bandwidths 1005.

With reference to FIG. 6 and descriptions thereof, in some embodiments, a method 1100 for stabilizing an OPM signal using a hybrid summing-node configuration is provided in FIG. 11. The method comprises in a first step 1101 sensing one or more magnetic-field components along an OPM sensitive axis using an OPM 105 disposed within internal compensation coils 115 to produce an OPM output 125. The method further comprises generating a feedback signal 1102 and processing the OPM output with a feedback controller to generate a drive 1103 that reduces magnetic-field variations over a bandwidth selected for the deployment, without requiring a predetermined bandwidth or crossover. The method further comprises generating a periodic cancellation drive 1104 wherein in parallel, processing the OPM output 125 through a periodic cancellation chain within SPU 130, including filter 132, phase 134, and gain 136, to isolate and target one or more periodic interference components that remain after operation of the feedback loop. The method further comprises summation and actuation 1105 including combining the feedback signal and the periodic cancellation drive 138 at a summing node within coil driver 140, and applying the combined drive to the internal compensation coil 115 to generate a composite cancellation field 120. In some embodiments, the feedback signal is alternatively applied to external coils 315 via a separate driver (not shown) while the periodic cancellation is applied to the internal coils 115. This hybrid configuration illustrated in FIG. 6 allows the feedback loop to operate with any suitable bandwidth while the AC periodic cancellation path provides targeted suppression of residual periodic interference, thereby improving overall performance without imposing a fixed frequency split between control paths.

The disclosed systems and methods offer several advantages over prior approaches.

First, reduced shielding requirements in that highly sensitive OPMs can operate in environments that might otherwise require costly passive shielding. Second, prevention of sensor saturation by cancelling strong periodic components at the sensor level, the OPM remains within its approximate linear range, e.g., in some embodiments below ~1 nT residual at the targeted frequency as shown in FIG. 5. Third, compatibility with downstream processing: maintaining linear, high-fidelity outputs enables array processing such as beamforming, signal space separation (SSS), and independent component analysis (ICA). Fourth, simplified array-level corrections: addressing large periodic fields locally at each sensor, mm-scale sensing volumes, reduces the burden of correcting array-scale gradients, e.g., MEG helmets. Fifth, leverage of existing hardware: internal compensation coils already present in many OPMs typically provide bandwidth>>kHz for this task. Sixth, latency tolerance: periodic phase adjustment compensates loop delays, suiting OPMs whose bandwidth may limit high-speed feedback. Seventh, no dedicated high-bandwidth reference sensors required: periodic cancellation does not depend on ultra-low-noise, high-BW reference sensors. Eighth, practical convergence: the periodic cancellation path can converge and restore operation even when initial fields push the sensor outside its linear range as shown in FIG. 5.

### EXAMPLES

### Example 1

In an example, to demonstrate the practical implementation and effectiveness of the described periodic cancellation system and method, the following experiment was conducted. A commercial triaxial QuSpin Zero-Field Magnetometer (QZFM), a type of ZF-OPM, was utilized. This sensor exhibits a sensitivity of approximately 15 fT/√Hz within its operational bandwidth, which has a −3 dB point around 130 Hz. As a triaxial sensor, it provides three independent outputs, as in FIG. 3 125x, 125y, 125z, corresponding to the magnetic field components measured along its three nominally orthogonal sensitive axes x, y, z. Crucially, the sensor head incorporates three independent, orthogonal internal compensation coils FIG. 3, 115x, 115y, 115z wrapped on the sensor head surface, with the alkali vapor cell 110 situated at their geometric center. These internal coils generate localized magnetic fields along each axis, specified to null DC fields within a range of approximately +/−80 nT, and are also used for internal modulation signals. The detailed principles of sensor operation are described extensively in scientific literature and product documentation [7], [8], [9]. In brief, the sensor utilized interactions between laser light, tuned to an alkali D1 transition, and the alkali vapor within the cell. A photodetector was used to measure changes in light transmission or rotation, which are processed by a remote electronics unit, being sensor electronics. This unit controlled laser parameters, cell temperature, and coil currents including modulation fields applied to the internal coils, and employs onboard Digital Signal Processors (DSPs) to demodulate the photodetector signal and output calibrated magnetic field readings for each axis. The electronics unit connected to the sensor head via an electrical cable.

The experiment was conducted inside a high-performance, three-layer magnetically shielded room (MSR). To simulate a more challenging environment representative of a lower-cost shield, e.g., 1-2 layers, or an unshielded setting, the door of the MSR was intentionally left fully open. This significantly reduced the MSR's shielding effectiveness, allowing substantial external interference into the measurement volume

Opening the MSR door resulted in two primary interference challenges including a large residual DC magnetic field component, measured at approximately 1000 nT, as well as significant AC periodic interference at the powerline frequency, 60 Hz, with amplitudes measured to be several tens of nT, e.g., 30-60 nT peak-to-peak, along various axes. This AC amplitude significantly exceeds the OPM's linear dynamic range of approximately +/−1 nT.

Due to the large residual DC field, 1000 nT exceeding the internal coils' +/−80 nT range, a set of external three-axis compensation coils, e.g., Helmholtz or similar configuration, as conceptually shown in FIG. 4, surrounding the QZFM sensor head was employed. Currents in these external coils were adjusted, either manually or using automated routines based on separate sensor readings [4], [6], as known in the art, to reduce the DC field components within the OPM's volume to below +/−80 nT. Once within this range, the QZFM's built-in internal closed-loop DC field nulling capability was activated. This internal loop uses the OPM's own readings and feedback to the internal coils to bring the final DC field experienced by the vapor cell very close to zero, <<1 nT, as required for optimal sensor operation. Although this internal loop operates using feedback, its limited loop gain at 60 Hz, despite a ~100 Hz (−3 dB) bandwidth, does not substantially suppress the large 60 Hz interference; periodic cancellation is provided by the AC path described below.

To implement the periodic cancellation system and method the following was performed. With the DC field properly nulled, the OPM was operational but its output was corrupted by a strong 60 Hz interference. The periodic cancellation system 100, 200 as illustrated in FIGS. 1-3, was utilized as follows. For signal acquisition the 125x, 125y, and 125z output signals from the QZFM sensor were processed by the onboard DSPs within the QZFM electronics controller. To isolate interference for each axis independently, a digital bandpass filter, centered at 60 Hz with a narrow bandwidth of 1 Hz. this narrow bandwidth sets the convergence/time-constant scale for tracking amplitude/phase drift near 60 Hz, was applied to the corresponding OPM output signal 125x, 125y, and 125z. This isolated the 60 Hz interference component from the desired signals and other noise. For phase and gain adjustment, the output of each 60 Hz bandpass filter was then subjected to a programmable time delay, equivalent to a phase shift, φ, and multiplied by a programmable gain factor, G in the SPU 130, for each axis 130x, 130y, 130z. For cancellation drive to the internal coil, the resulting processed signal FIG. 3, 138x, 138y, 138z, being filtered, phase-shifted, and gain-adjusted, for each axis, x, y, and z, was fed internally to the driver circuit 140x, 140y, 140z for the corresponding internal compensation coil 115x, 115y, 115z. For tuning, the phase delay (φ) and gain (G) parameters for each of the three independent cancellation loops 142x, 142y, 142z were adjusted to minimize the residual 60 Hz signal observed at the OPM output for that axis. The objective was to configure the internal coils to generate a 60 Hz magnetic field equal in amplitude and approximately 180 degrees out of phase with the ambient 60 Hz interference along each respective axis

Upon activation and tuning of the three-axis periodic cancellation system, the 60 Hz interference measured by the QZFM sensor was largely suppressed along all three axes. The residual 60 Hz field amplitude was reduced to well below the sensor's +/−1 nT linear operating range, consistent with the conceptual illustration in FIG. 5. As a result, the QZFM sensor could operate reliably and provide high-fidelity measurements of other magnetic field phenomena, effectively unimpeded by the strong ambient powerline noise, despite the MSR door being open The bandwidth of the periodic cancellation loop in this implementation was primarily limited by the narrow 1 Hz bandpass filter used to isolate the 60 Hz signal. Consequently, the system's characteristic time to fully react and adapt to abrupt changes in the amplitude or phase of the 60 Hz interference was on the order of 1 second, T≈1/Δf. This response time is considered adequate for many applications, as powerline interference characteristics typically do not change on such rapid timescales. In other embodiments, a wider BPF, e.g., 2-5 Hz, trades faster convergence for reduced selectivity when the interference frequency is less stable.

### Example 2

To further demonstrate capability, a multi-tone test was performed. While 60 Hz periodic cancellation was active, a controlled periodic field at 75 Hz was injected using an external source coil, creating simultaneous interference at 60 Hz and 75 Hz. The OPM's DSP-based periodic cancellation system was configured to suppress both frequencies concurrently. For each axis (X, Y, Z), two parallel processing paths were implemented: Path 1: BPF @ 60 Hz->phase adjust (φ₆₀)->gain (φ₆₀); Path 2: BPF @ 75 Hz->phase adjust (φ₇₅)->gain (φ₇₅).

For a given axis, the outputs of the two paths were summed digitally and used to drive the corresponding internal compensation coil via the coil driver. Independent tuning of {φ₆₀, φ₆₀} and {φ₇₅, φ₇₅} was performed per axis to minimize residuals at both 60 Hz and 75 Hz.

The system achieved simultaneous suppression of both the 60 Hz powerline component and the 75 Hz injected interference along all three axes, confirming that multiple distinct periodic sources can be cancelled concurrently using parallel periodic cancellation paths.

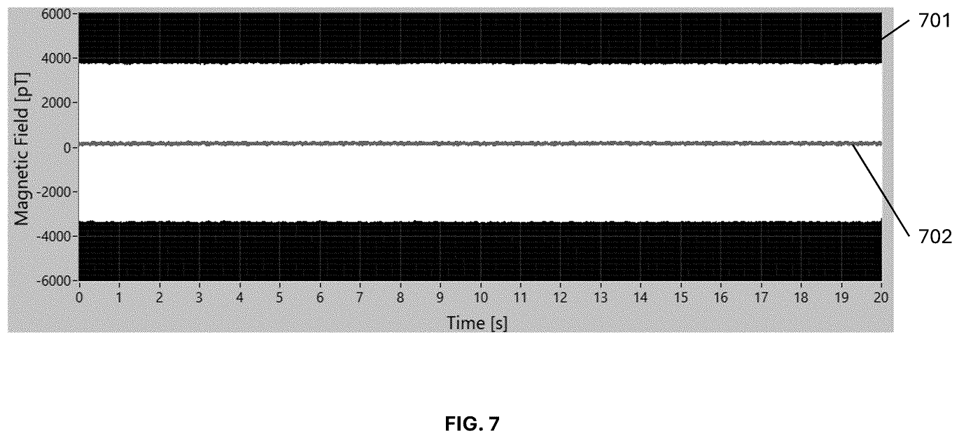

The effectiveness of the periodic cancellation is illustrated in FIG. 7. Only the Z-axis is shown however the X and Y behaved similarly. The upper trace 701 with cancellation off shows the OPM saturating near ±4000 pT, indicating interference well beyond the linear range (>8 nT p-p). The lower trace 702 with cancellation on shows the residual near 0 pT (≈1 nT), restoring linear operation. Remaining fluctuations reflect baseline noise and other field components.

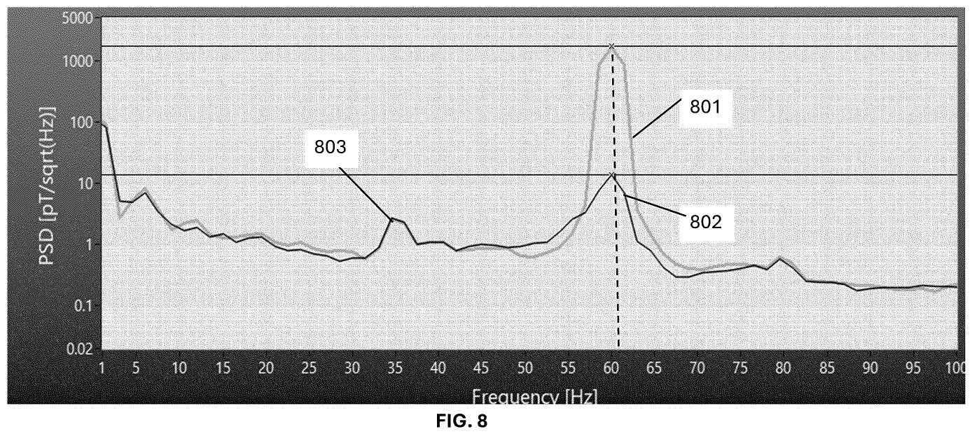

FIG. 8 shows the corresponding amplitude spectral density (PSD). The upper trace 801, with cancellation off, exhibits a dominant 60 Hz peak exceeding 1000 pT/√Hz. The lower trace 802, with cancellation on, shows the 60 Hz peak dramatically reduced to about 10 pT/√Hz in this measurement, consistent with the time-domain restoration of linear operation. Spectral features not targeted by the 60 Hz path, e.g., a peak near 30-35 Hz, 803, remain largely unchanged, demonstrating frequency selectivity.

Although specific embodiments have been described, numerous modifications and variations are possible without departing from the scope of the disclosure. No limitation to the particular embodiments is intended or should be inferred. Each apparatus embodiment described has multiple equivalents.

### BIBLIOGRAPHY

[1] J. C. Allred, R. N. Lyman, T. W. Kornack, and M. V. Romalis, “High-Sensitivity Atomic Magnetometer Unaffected by Spin-Exchange Relaxation,” Phys. Rev. Lett., vol. 89, no. 13, p. 130801, 2002, doi: 10.1103/PhysRevLett.89.130801.
[2] V. Shah, S. Knappe, P. D. D. Schwindt, and J. Kitching, “Subpicotesla atomic magnetometry with a microfabricated vapour cell,” Nat Photon, vol. 1, no. 11, pp. 649-652, November 2007, doi: 10.1038/nphoton.2007.201.
[3] N. Holmes et al., “Enabling ambulatory movement in wearable magnetoencephalography with matrix coil active magnetic shielding,” NeuroImage, vol. 274, p. 120157, July 2023, doi: 10.1016/j.neuroimage.2023.120157.
[4] E. Boto et al., “Moving magnetoencephalography towards real-world applications with a wearable system,” Nature, vol. 555, no. 7698, pp. 657-661, March 2018, doi: 10.1038/nature26147.
[5] A. Hillebrand et al., “Non-invasive measurements of ictal and interictal epileptiform activity using optically pumped magnetometers,” Sci. Rep., vol. 13, no. 1, Art. no. 1, March 2023, doi: 10.1038/s41598-023-31111-y.
[6] N. Holmes et al., “Wearable magnetoencephalography in a lightly shielded environment,” IEEE Trans. Biomed. Eng., vol. PP, September 2024, doi: 10.1109/TBME.2024.3465654.
[7] E. Boto et al., “Triaxial detection of the neuromagnetic field using optically-pumped magnetometry: feasibility and application in children,” NeuroImage, vol. 252, p. 119027, May 2022, doi: 10.1016/j.neuroimage.2022.119027.
[8] M. Rea et al., “A 90-channel triaxial magnetoencephalography system using optically pumped magnetometers,” Ann. N. Y. Acad. Sci., vol. n/a, no. n/a, doi: 10.1111/nyas.14890.
[9] U.S. Pat. No. 10,775,450B1, “Zero field parametric resonance magnetometer with triaxial sensitivity,” to inventors V. Shah, C. Doyle, and J. Osborne, Sep. 15, 2020.

What is claimed is:

1. A system for mitigating periodic magnetic interference, the system comprising:
a) an optically pumped magnetometer (OPM) sensor having at least one sensitive axis and at least one of an internal compensation coil or a closely affixed external compensation coil aligned with the at least one sensitive axis, wherein the at least one of an internal compensation coil or a closely affixed external compensation coil is configured to generate a magnetic field local to the sensor;
b) a signal processing unit configured to receive at least one output signal from the OPM sensor, isolate at least one periodic interference component at a target frequency from the at least one output signal, and generate at least one periodic processed signal by applying a programmable phase and a programmable gain to the at least one isolated periodic interference component;
c) a coil driver configured to drive the at least one of an internal compensation coil or a closely affixed external compensation coil based on the at least one periodic processed signal to generate at least one cancellation magnetic field;
d) wherein the at least one cancellation magnetic field substantially counteracts the at least one isolated periodic interference component at the OPM sensor; and
e) wherein the programmable phase is selected modulo 2π to account for an aggregate system latency, thereby enabling effective cancellation at the target frequency for at least one of a fixed and a bounded aggregate latency.

2. The system of claim 1, wherein the signal processing unit is configured to use a periodicity of the at least one periodic interference component to select, for the at least one periodic processed signal at the target frequency, a phase modulo 2π that accommodates the aggregate system latency, thereby enabling cancellation at the target frequency without requiring a control loop having bandwidth sufficient to suppress the target frequency.

3. The system of claim 1, wherein the at least one output signal of the OPM sensor is initially non-linear or saturated due to the at least one periodic interference component and activation of the at least one periodic processed signal reduces the at least one periodic interference component such that the at least one output signal of the OPM sensor is reduced to within a linear operating range.

4. The system of claim 1, wherein the signal processing unit is configured to derive at least one periodic interference component from at least one of a mains-locked timebase and a reference magnetometer, and apply the programmable phase and the programmable gain to synthesize the at least one periodic processed signal.

5. The system of claim 1, wherein the signal processing unit is configured to isolate at least two periodic interference components and to generate at least two corresponding periodic processed signals that are combined to drive at least two compensation coils, each of the at least two compensation coils being one of the at least one of an internal compensation coil or a closely affixed external compensation coil.

6. The system of claim 1, wherein the signal processing unit is configured to isolate at least three periodic interference components and to generate at least three corresponding periodic processed signals that are combined to drive at least three compensation coils, each of the at least three compensation coils being one of the at least one of an internal compensation coil or a closely affixed external compensation coil.

7. The system of claim 6, wherein the signal processing unit is configured to perform independent isolation and phase/gain selection for the respective at least three periodic interference components to produce at least three corresponding periodic processed signals.

8. The system of claim 1, wherein the signal processing unit is configured to adaptively update at least one of the programmable phase and the programmable gain over time to maintain effective cancellation at the target frequency.

9. The system of claim 1, wherein the signal processing unit is further configured to generate a low-frequency feedback drive based on at least one output signal from the OPM sensor, and wherein the coil driver comprises a summing node configured to combine the low-frequency feedback drive with the at least one periodic processed signal to drive the at least one of an internal compensation coil or a closely affixed external compensation coil.

10. The system of claim 9, wherein the low-frequency feedback drive reduces DC and low-frequency variations and the at least one periodic processed signal reduces periodic components not fully removed by the low-frequency feedback drive.

11. The system of claim 1, wherein the signal processing unit comprises at least one filter configured to isolate the at least one periodic interference component, a phase-shift module, and a gain module implemented in at least one of a digital signal processor (DSP), a field-programmable gate array (FPGA), and a microprocessor executing program instructions.

12. The system of claim 1, wherein the at least one periodic processed signal is synthesized digitally by the signal processing unit.

13. The system of claim 1, wherein the programmable phase is pre-calibrated for one or more target frequencies and optionally refined during operation.

14. A method for mitigating periodic magnetic interference in an optically pumped magnetometer (OPM), the method comprising:
a) operating an OPM sensor having at least one compensation coil aligned with at least one sensitive axis;
b) receiving at least one output signal indicative of a magnetic field along the at least one sensitive axis;
c) isolating at least one periodic interference component at a target frequency from the at least one output signal;
d) generating at least one periodic processed signal by applying a programmable phase and a programmable gain to the at least one isolated periodic interference component;
e) driving the at least one compensation coil with the at least one periodic processed signal to synthesize at least one cancellation magnetic field that substantially counteracts the isolated at least one periodic interference component at the sensor; and
f) wherein the programmable phase is selected modulo 2π to account for an aggregate system latency and time delay, thereby enabling effective cancellation at the target frequency for at least one of a fixed and a bounded aggregate latency and time delay.

15. The method of claim 14, wherein cancellation at the target frequency uses the periodicity of the at least one periodic interference such that at least one of a fixed and a bounded system latency, and the time delay, are accommodated by phase selection modulo 2π, without requiring a control loop, with bandwidth sufficient to suppress the target frequency.

16. The method of claim 14, further comprising initializing from a state in which the at least one output signal is saturated or non-linear due to the at least one periodic interference and continuing operation until the at least one periodic interference is reduced to within a linear operating range of the at least one output signal.

17. The method of claim 14, further comprising isolating at least two periodic interference components and generating at least two corresponding periodic processed signals that are combined to drive the at least one compensation coil.

18. The method of claim 14, wherein the OPM sensor is triaxial and the method is performed per axis with independent phase and gain selection for each respective sensitive axis.

19. The method of claim 14, further comprising adaptively updating at least one of the programmable phase and the programmable gain over time to maintain effective cancellation at the target frequency.

20. The system of claim 1, wherein a low-frequency feedback drive is applied to an external actuator coil distinct from the at least one of an internal or a closely affixed external compensation coil, and the periodic processed signal is applied to the at least one of an internal or a closely affixed external compensation coil.

21. A system comprising:
a plurality of optically pumped magnetometer (OPM) sensors, wherein each of the plurality of OPM sensors comprises at least one sensitive axis and at least one of an internal and a closely affixed external compensation coil aligned with the at least one sensitive axis;
wherein each of the at least one of an internal and a closely affixed external compensation coil is configured to generate a magnetic field local to one of each of the plurality of OPM sensors;
a signal processing unit configured to isolate, for each of the plurality of OPM sensors, at least one periodic interference component at a target frequency from at least one output signal of each of the plurality of OPM sensors, and to generate a periodic processed signal for each of the at least one output signals by applying a programmable phase selected modulo 2π and a programmable gain; and
a coil driver configured for each of the plurality of OPM sensors to drive the at least one of an internal or a closely affixed external compensation coil based on the periodic processed signal to synthesize a cancellation magnetic field that substantially counteracts the at least one periodic interference component at each of the plurality of OPM sensors.
